(19) United States
(12) Patent Application Publication
(10) Pub. No.: US 2017/0200507 A1
(43) Pub. Date: Jul. 13, 2017

(54) MEMORY SYSTEM INCLUDING MEMORY DEVICE

(71) Applicant: SAMSUNG ELECTRONICS CO., LTD., Suwon-si (KR)

(72) Inventors: Yoon Jae JEONG, Anyang-si (KR); Je Min RYU, Seoul (KR)

(21) Appl. No.: 15/391,883

(22) Filed: Dec. 28, 2016

(30) Foreign Application Priority Data
Jan. 11, 2016 (KR) 10-2016-0003164

(51) Int. Cl. G11C 17/18; G11C 29/04; G11C 17/16

(52) U.S. Cl. CPC G11C 17/18; G11C 17/16; G11C 29/04

(57) ABSTRACT

A memory system includes a plurality of first signal lines to connect a plurality of memory devices to one another. The memory devices include a first memory device and at least one second memory device. The first memory device has at least one fuse cell and outputs fuse information set based on whether each of the at least one fuse cell is programmed. The at least one second memory device receives the fuse information and selectively activates the first signal lines based on the fuse information. The at least one second memory device simultaneously operates based on the fuse information received from the first memory device.

### CROSS-REFERENCE TO RELATED APPLICATION

Korean Patent Application No. 10-2016-0003164, filed on Jan. 11, 2016, and entitled, “Memory System Including Memory Device,” is incorporated by reference herein in its entirety.

### BACKGROUND

1. Field

One or more embodiments described herein relate to a memory system including a memory device.

2. Description of the Related Art

Various multichip packaging methods have been developed for manufacturing nonvolatile memories, volatile memories, and other highly integrated semiconductor devices. One method involves stacking semiconductor chips together to form a memory device having a three-dimensional structure. Such a memory device includes a buffer die and a plurality of core dies electrically connected to one another via through-silicon vias (TSVs). Each of the dies may include a circuit for storing the same information for the TSVs. This may increase the size of the entire chip.

### SUMMARY

In accordance with one or more embodiments, a memory system including a plurality of memory devices; and a plurality of first signal lines to connect the memory devices to one another, wherein the memory devices include: a first memory device including at least one fuse cell, the first memory device to output fuse information set based on whether each of the at least one fuse cell is programmed; and at least one second memory device to receive the fuse information and to selectively activate the first signal lines based on the fuse information, wherein the at least one second memory device simultaneously operates based on the fuse information received from the first memory device.

In accordance with one or more other embodiments, an apparatus includes a first die; a second die; a through-silicon via (TSV) between the first and second dies, wherein the first die includes a storage area to store fuse information for the second die and wherein the fuse information is indicative of whether a signal line between the first and second dies is defective.

### BRIEF DESCRIPTION OF THE DRAWINGS

Features will become apparent to those of skill in the art by describing in detail exemplary embodiments with reference to the attached drawings in which:

FIG. 1 illustrates an embodiment of a memory system;

FIG. 2 illustrates an embodiment of a memory device;

FIG. 3 illustrates a more detailed embodiment of the memory device;

FIG. 4 illustrates a more detailed embodiment of the memory device;

FIG. 5 illustrates an embodiment of a timing diagram for the memory device;

FIG. 6 illustrates another embodiment of a memory device;

FIG. 7 illustrates another embodiment of a memory system;

FIG. 8 illustrates an embodiment of a computer system;

FIG. 9 illustrates another embodiment of a computer system;

FIG. 10 illustrates another embodiment of a computer system; and

FIG. 11 illustrates another embodiment of a computer system.

### DETAILED DESCRIPTION

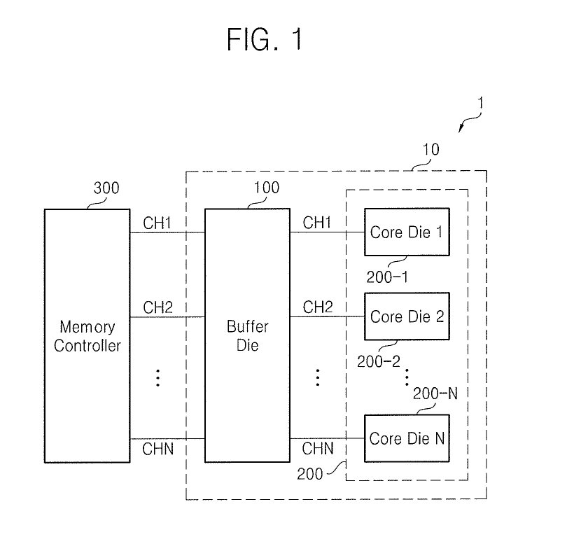

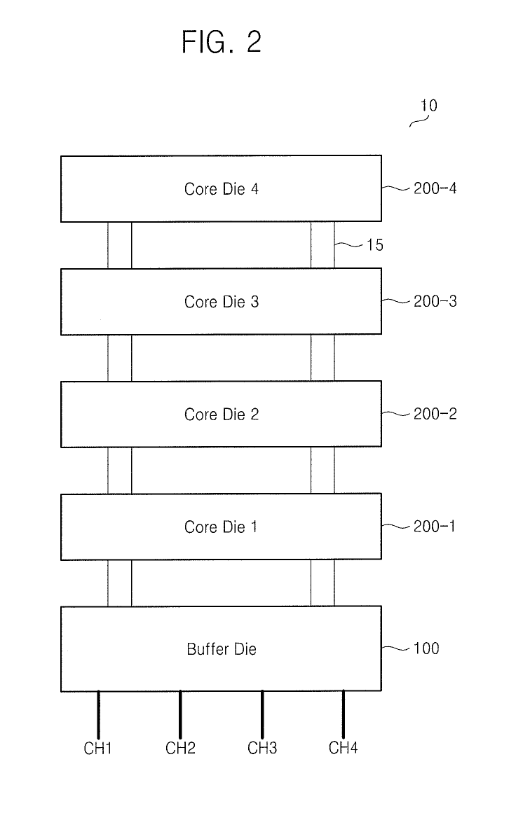

FIG. 1 illustrates an embodiment of a memory system 1, and FIG. 2 illustrates an embodiment of a memory device 10 that may be included in the memory system 1.

Referring to FIGS. 1 and 2, the memory system 1 includes the memory device 10 and a memory controller 300. The memory device 10 may include a buffer die 100 and N core dies 200 (first to N^{th} core dies 200-1 to 200-N, where N denotes an integer which is greater than or equal to 2). The first to N^{th} core dies 200-1 to 200-N respectively communicate with the memory controller 300 via independent channels CH1 to CHN. In particular, the first to N^{th} core dies 200-1 to 200-N communicate with the memory controller 300 via the buffer die 100.

Each of the first to N^{th} core dies 200-1 to 200-N may be referred to as a core memory, which includes a plurality of memory cells and an access circuit for writing data to or reading data from the memory cells. The first to N^{th} core dies 200-1 to 200-N may be in 1:1 correspondence with the first to N^{th} channels CH1 to CHN. For example, the i^{th} core die 200-i may correspond to the i^{th} channel CHi, etc., where ‘i’ is an integer ranging from 1 to N.

In one embodiment, the correspondence of the first to N^{th} core dies 200-1 to 200-N to the first to N^{th} channels CH1 to CHN may include the case where signals (e.g., address information ADD, a command CMD, a data signal DQ, and a data strobe signal DQS) related to the core dies 200-1 to 200-N are transmitted/received via the first to N^{th} channels CH1 to CHN corresponding to the first to N^{th} core dies 200-1 to 200-N. Thus, in one embodiment, signals related to one of the first to N^{th} core dies 200-1 to 200-N may not be transmitted/received via channels which do not correspond to this core die.

In another embodiment, the first to N^{th} core dies 200-1 to 200-N may be in 1:n or m:1 correspondence with the first to N^{th} channels CH1 to CHN, where n and m are integers. Each of the first to N^{th} core dies 200-1 to 200-N may operate by receiving the address information ADD and the command CMD from the memory controller 300 via a corresponding channel among the first to N^{th} channels CH1 to CHN, and may transmit or receive data signal DQ and data strobe signal DQS to or from memory controller 300.

The buffer die 100 may be referred to as a buffer memory, which delivers commands and data to be transmitted/received between the memory controller 300 and the first to N^{th} core dies 200-1 to 200-N. For example, the buffer die 100 may receive commands and data from the memory controller 300 via the channels CH1 to CHN, and transmit them to the core dies 200-1 to 200-N via the channels CH1 to CHN, The buffer die 100 may also receive data from the core dies 200-1 to 200-N and transmit the data to the memory controller 300.

The memory controller 300 may control overall operations (e.g., read operation, write operation, refresh operation, etc.) of the memory device 10. In one embodiment, the memory controller 300 may be included as part of a system-on-chip (SoC) or an application processor (AP).

Referring to FIG. 2, the memory device 10 may have a three-dimensional (3D) stack structure according to one embodiment. The memory device 10 includes the buffer die 100 and four core dies 200-1 to 200-4, where In other embodiments, the memory device 10 may include a different number of core dies.

The buffer die 100 and the first to fourth core dies 200-1 to 200-4 may have a stack structure. For example, as illustrated in FIG. 2, the buffer die 100 may be at the bottom of the stack structure, the first core die 200-1 may be stacked on the buffer die 100, the second core die 200-2 may be stacked on the first core die 200-1, the third core die 200-3 may be stacked on the second core die 200-2, and the fourth core die 200-4 may be stacked on third core die 200-3. Each of the buffer die 100 and the first to fourth core dies 200-1 to 200-4 may be electrically connected to an adjacent die via one or more TSVs 15.

The buffer die 100 may include logic to transmit/receive signals to/from the memory controller 300 via the first to fourth channels CH1 to CH4 and to perform or process a request (e.g., read/write request) from the memory controller 300.

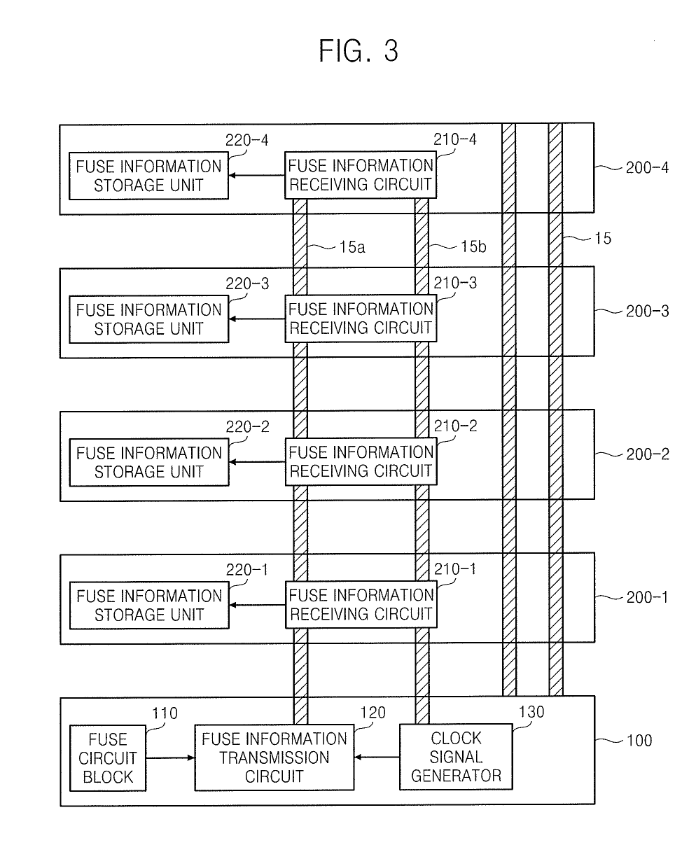

FIG. 3 illustrates a more detailed embodiment of the memory device 10, in which one of a die 100 or first to fourth core dies 200-1 to 200-4 operate as a master die and the other dies operate as slave dies. In the present embodiment, the buffer die 100 operates as a master die and the first to fourth core dies 200-1 to 200-4 operate as slave. In other embodiments, one of the first to fourth core dies 200-1 to 200-4 may operate as a master die and the buffer die 100 and the other core dies may operate as slave dies.

Referring to FIGS. 1 to 3, the buffer die 100 may include a fuse circuit block 110, a fuse information transmission circuit 120, and a clock signal generator 130. Each of the core dies 200-1 to 200-4 may include a corresponding one of fuse information receiving circuits 210-1 to 210-4 and a corresponding one of fuse information storage units 220-1 to 220-4.

The buffer die 100 and the core dies 200-1 to 200-4 may be connected to one another via the TSVs 15, a fuse information signal line 15a, and a clock signal line 15b for transmitting/receiving control signals and data to/from one another.

The fuse circuit block 110 may include a plurality of fuse cells. Fuse information may be set in the fuse cells according to whether they are programmed. The fuse cells may output the set fuse information. In one embodiment, the fuse cells may be anti-fuse cells.

The fuse information may include information representing whether the TSVs 15, through which control signals and data are transmitted between the buffer die 100 and the core dies 200-1 to 200-4, are defective or not. In addition, the fuse information may include various types of information for changing the characteristics of the dies in the memory device 10.

The fuse information transmission circuit 120 may transmit the fuse information output from the fuse circuit block 110 to the core dies 200-1 to 200-4, via the fuse information signal line 15a, based on a fuse information clock signal.

The clock signal generator 130 may generate the fuse information clock signal to be synchronized with the fuse information for output to the fuse information transmission circuit 120. Furthermore, the clock signal generator 130 may output the fuse information clock signal to the fuse infatuation receiving circuits 210-1 to 210-4 corresponding to the core dies 200-1 to 200-4 via the clock signal line 15b. In one embodiment, the fuse information signal line 15a and the clock signal line 15b may include TSVs.

The fuse information receiving circuits 210-1 to 210-4 may receive the fuse information via the fuse information signal line 15a and the fuse information clock signal via the clock signal line 15b. The fuse information receiving circuits 210-1 to 210-4 may receive the fuse information in synchronization with the fuse information clock signal, and may store the fuse information in the fuse information storage units 220-1 to 220-4.

The fuse information storage units 220-1 to 220-4 may receive and store the fuse information from the fuse information receiving circuits 210-1 to 210-4. Each of the core dies 200-1 to 200-4 may receive and store the fuse information from the buffer die 100, and selectively activate the TSVs 15 based on the stored fuse information.

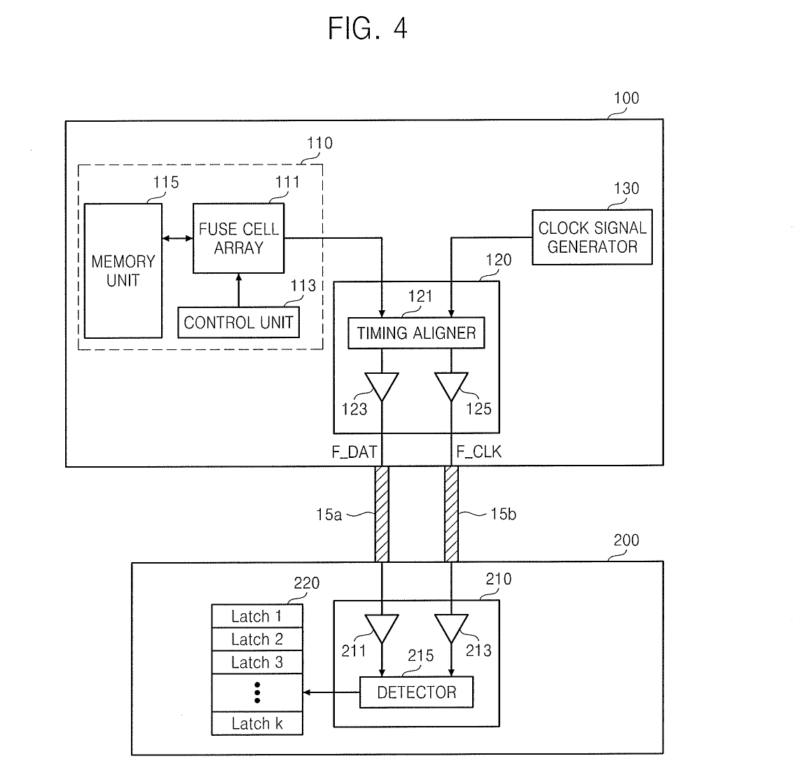

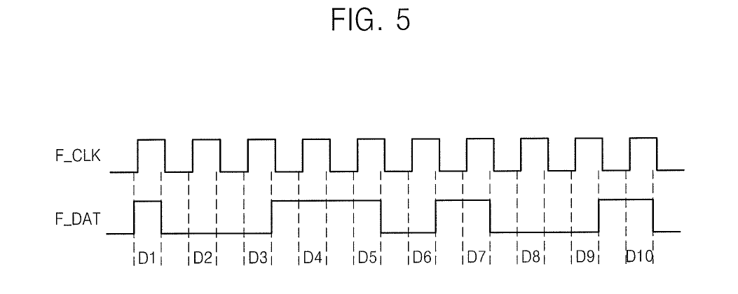

FIG. 4 illustrates a more detailed embodiment of the memory device in FIG. 3, and FIG. 5 is an embodiment of a timing diagram illustrating operation of the memory device. For illustrative purposes only, the embodiment of FIG. 4 will be described with respect to only a buffer die 100 and one core die 200 below.

Referring to FIGS. 4 and 5, in the buffer die 100, a fuse circuit block 110 may include a fuse cell array 111, a control unit 113, a memory unit 115, and a fuse information transmission circuit 120 may include a timing aligner 121, a first output buffer 123, and a second output buffer 125.

The fuse cell array 111 may have an array structure including fuse cells at intersections of a plurality of rows and a plurality of columns. For example, when the fuse cell array 111 includes m rows and n columns, the fuse cell array 111 may include mxn fuse cells, where m and n are integers. Fuse information may be set in the fuse cells according to whether or not they are programmed.

The control unit 113 may control the fuse cell array 111 to output the fuse information to the fuse information transmission circuit 120. In addition, the control unit 113 may control the fuse cell array 111 to store the fuse information, which is set in the fuse cell array 111, in a memory unit 115. In this case, the memory unit 115 may include, for example, a plurality of latches or a plurality of registers.

The timing aligner 121 may convert the fuse information output from the fuse cell array 111 into serial data, and may output the serial data in synchronization with a fuse information clock signal from the clock signal generator 130. In this case, the clock signal generator 130 may transmit the same fuse information clock signal F_CLK to the core dies 200-1 to 200-N of FIG. 1, in order to transmit serial data F_DAT including a plurality of pieces of fuse information to the core dies 200-1 to 200-N. For example, the timing aligner 121 convert a plurality of pieces of fuse information corresponding to the TSVs 15 to serial data, so that the pieces of fuse information may be output to the core die 200 via one fuse information signal line 15a.

The first output buffer 123 may transmit the serial data F_DAT from the timing aligner 121 to the fuse information receiving circuit 210 via the fuse information signal line 15a. The second output buffer 125 may transmit the fuse information clock signal F_CLK from the timing aligner 121 to the fuse information receiving circuit 210 via a clock signal line 15b.

The core die 200 may include a fuse information receiving circuit 210 and a fuse information storage unit 220. The fuse information receiving circuit 210 may include a first input buffer 211, a second input buffer 213, and a detector 215. The first input buffer 211 may receive the serial data F_DAT transmitted via the fuse information signal line 15a. The second input buffer 213 may receive and output the fuse information clock signal F_CLK transmitted via the clock signal line 15b.

The detector 215 may detect the serial data F_DAT based on the fuse information clock signal F_CLK and may output the serial data F_DAT to the fuse information storage unit 220.

The fuse information storage unit 220 may include a plurality of latches, e.g., latch 1 to latch k, where k is an integer greater than or equal to 2. In one embodiment, the fuse information storage unit 210 may include a plurality of registers. The fuse information storage unit 220 may receive and store the serial data F_DAT, e.g., the pieces of fuse information stored in the fuse cells of the fuse cell array 111. Then, the core die 200 may control transmission/reception of a command and/or data among the other dies 100 and 200-1 to 200-4, based on the pieces of fuse information stored in the fuse information storage unit 220.

Referring to FIG. 5, when the serial data F_DAT includes information representing whether ten TSVs 15 are defective or not, ten pieces of serial data Dl to D10 may be transmitted from the fuse information transmission circuit 120 to the fuse information receiving circuit 210 based on the fuse information clock signal F_CLK. In this case, fuse information storage unit 220 may include ten latches latch 1 to latch 10.

A rising point of the fuse information clock signal F_CLK may be later than that of the serial data F_DAT, so that effective serial data F_DAT may be transmitted from the fuse information transmission circuit 120. For example, fuse information corresponding to logic high may be output when a fuse cell is programmed, and fuse information corresponding to logic low may be output when the fuse cell is not programmed. In one embodiment, the buffer die 100 and the plurality of core dies 200-1 to 200-N connected to one another via the TSVs 15 may operate by sharing the serial data F_DAT including the fuse information.

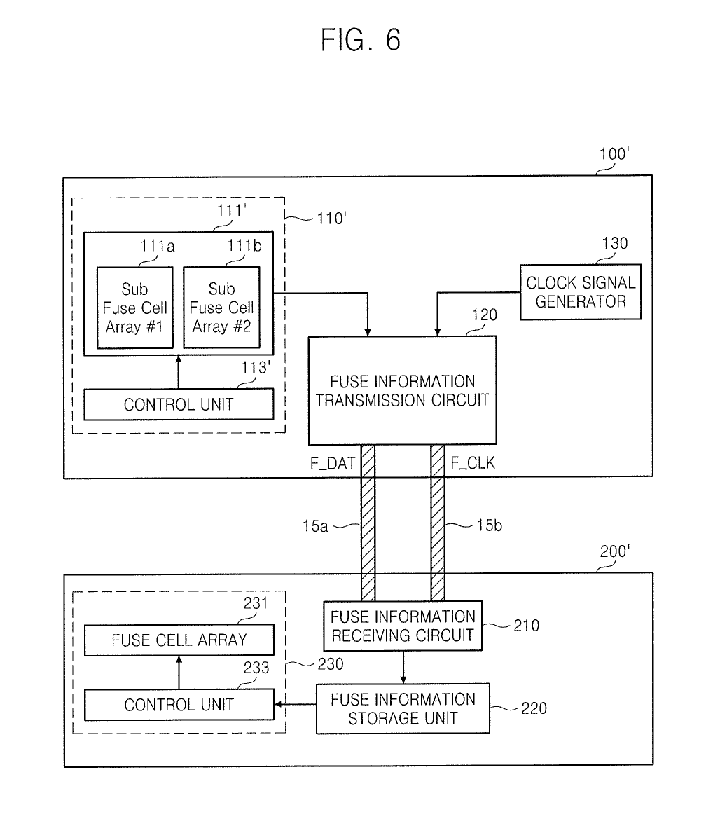

FIG. 6 illustrates another embodiment of a memory device. Referring to FIG. 6, a fuse cell array 111′ of the buffer die 100′ may include a first sub-fuse cell array 111a and a second sub-fuse cell array 111b. The first sub-fuse cell array 111a may include a plurality of first fuse cells to store first fuse information representing whether memory cells in the buffer die 100′ are defective. The second sub-fuse cell array 111b may include a plurality of second fuse cells to store second fuse information representing whether the TSVs 15 are defective.

A control unit 113′ of the buffer die 100′ may control the fuse cell array 111′ to output only the second fuse information stored in the second sub-fuse cell array 111b to the fuse information transmission circuit 120. In addition, the control unit 113′ may control operation of the buffer die 100′ based on the first fuse information and the second fuse information.

A core die 200′ may include a fuse circuit block 230, compared to the core die 200 in FIG. 4. The fuse circuit block 230 may include a fuse cell array 231 and a control unit 233. Similar to the first sub-fuse cell array 111a, the fuse cell array 231 may include a plurality of fuse cells to store first fuse information representing whether memory cells in the core die 200′ are defective.

The control unit 233 may control operation of the core die 200′ based on the first fuse information stored in the fuse cell array 231. Furthermore, the control unit 233 may control the operation of the core die 200′ based on the second fuse information transmitted from the buffer die 100′ and stored in a fuse information storage unit 220.

Thus, a fuse cell storing information representing whether the TSVs 15 are defective may be included in only one of a plurality of dies. The other dies may share this information, thereby decreasing the area of the memory device 10.

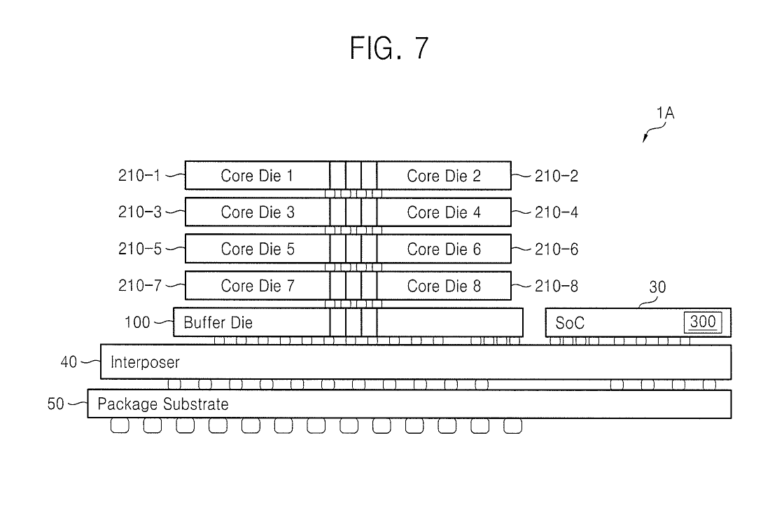

FIG. 7 illustrates another embodiment of a memory system 1A which may include a memory device, a SoC 30, an interposer 40, and a package substrate 50. The memory device may be a high-bandwidth memory (HBM) device, and include a buffer die 100 and first to eighth core dies 210-1 to 210-8. The SoC 30 may include a memory controller 300. The interposer 40 connects the SoC 30 and the buffer die 100 to each other using a wire. The package substrate 50 supports the SoC 30 and the memory device, and connects the SoC 30 and the memory device to a mother board.

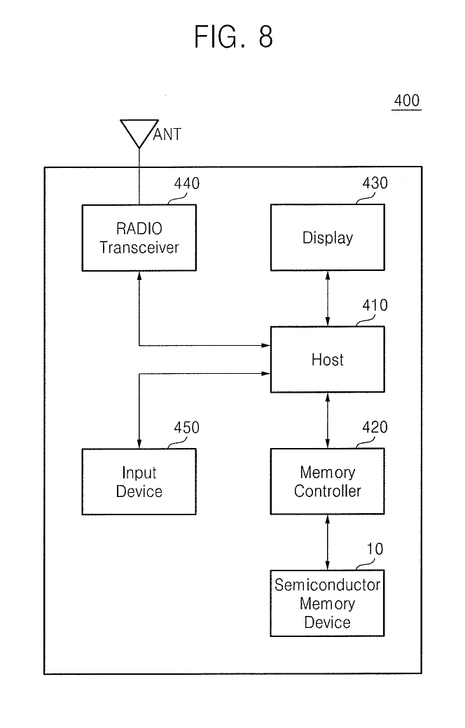

FIG. 8 illustrates an embodiment of a computer system 400 including the memory device 10 in FIG. 1. Referring to FIGS. 1 and 8, the computer system 400 may be implemented, for example, as a cellular phone, a smart phone, a personal digital assistant (PDA), or a wireless communication device.

The computer system 400 includes the memory device 10 and a memory controller 420 for controlling operation of the memory device 10. The memory controller 420 may control a data access operation (e.g., a write operation or a read operation) of the memory device 10 according to control of a host 410. The memory controller 420 may be, for example, the memory controller 300 in FIG. 1.

Data of the memory device 10 may be displayed through a display 430 according to control of the host 410 and the memory controller 420. A radio transceiver 440 may transmit or receive radio signals through an antenna ANT. The radio transceiver 440 may convert radio signals received through the antenna ANT to signals for processing by the host 410. Accordingly, the host 410 may process the signals from the radio transceiver 440 and may transmit the processed signals to the memory controller 420 or the display 430. The memory controller 420 may store the signals processed by the host 410 in the memory device 10. The radio transceiver 440 may also convert signals from the host 410 to radio signals and may output the radio signals to an external device through the antenna ANT.

An input device 450 enables control signals for controlling operation of the host 410 or data to be processed by the host 410 to be input to the memory device 10. The input device 450 may be implemented as a pointing device, e.g., a touch pad or a computer mouse, a keypad, or a keyboard.

The host 410 may control operation of the display 430 to display data output from the memory controller 420, data output from the radio transceiver 440, or data output from the input device 450. The memory controller 420, which controls operations of the memory device 10, may be implemented as part of the host 410 or a separate chip.

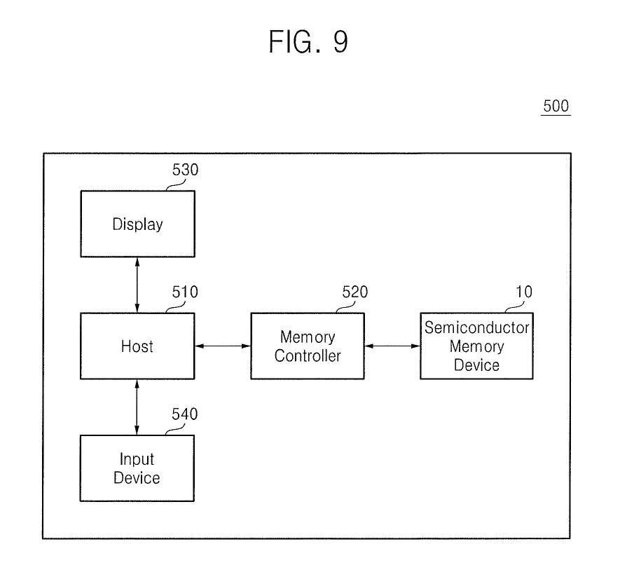

FIG. 9 illustrates another embodiment of a computer system 500 which includes the memory device 10 in FIG. 1. The computer system 500 may be implemented, for example, as a personal computer (PC), a network server, a tablet PC, a net-book, an e-reader, a personal digital assistant (PDA), a portable multimedia player (PMP), an MP3 player, or an MP4 player.

The computer system 500 includes a host 510, the memory device 10, a memory controller 520 for controlling the data processing operations of the memory device 10, a display 530, and an input device 540. The host 510 may display data stored in the memory device 10 through the display 530 according to data input through the input device 540. The input device 540 may be implemented by a pointing device, e.g., a touch pad or a computer mouse, a keypad, or a keyboard.

The host 510 may control the overall operation of the computer system 500 and operations of the memory controller 520. The memory controller 520 may be, for example, the memory controller 300 in FIG. 1. According to some embodiments, the memory controller 520, which may control operations of the memory device 10, may be implemented as part of the host 510 or a separate chip.

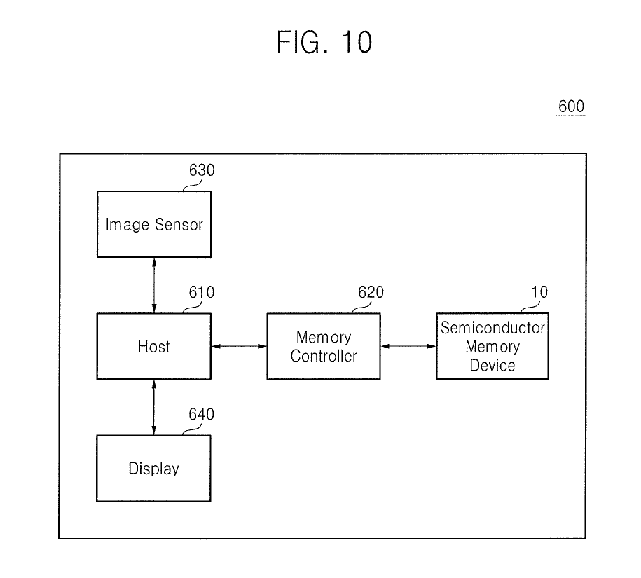

FIG. 10 illustrates another embodiment of a computer system 600 which includes memory device 10 in FIG. 1. The computer system 600 may be implemented as an image processing device, e.g., a digital camera, a cellular phone equipped with a digital camera, or a smart phone equipped with a digital camera.

The computer system 600 includes a host 610, the memory device 10 and a memory controller 620 for controlling data processing operations (e.g., a write operation or a read operation) of the memory device 10. The computer system 600 further includes an image sensor 630 and a display 640.

The image sensor 630 in the computer system 600 converts optical images to digital signals for output to the host 610 or the memory controller 620. The digital signals may be controlled by the host 610 for display through the display 640 or may be stored in the memory device 10 through the memory controller 620.

Data stored in the memory device 10 may be displayed through the display 640 according to control of the host 610 or the memory controller 620. The memory controller 620 may control operations of the memory device 10 and may be implemented as part of the host 610 or as a separate chip. The memory controller 620 may be, for example, the memory controller 300 in FIG. 1.

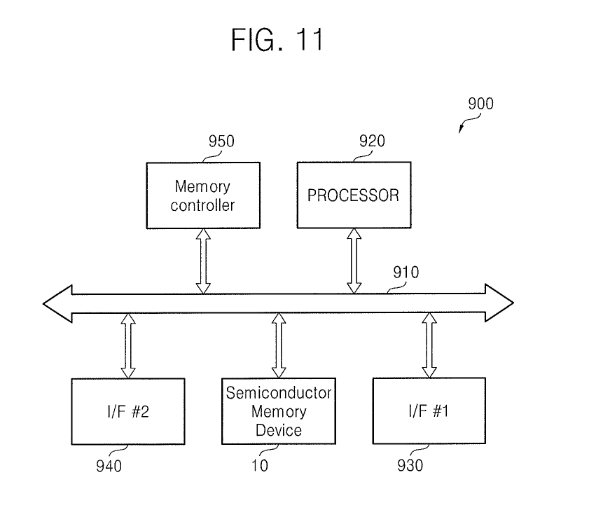

FIG. 11 illustrates another embodiment of a computer system 900 which includes the memory device 10 in FIG. 1. Referring to FIGS. 1 and 11, the computer system 900 may include a memory device (semiconductor memory device) 10, a memory controller 950, a processor 920, a first interface 930, and a second interface 940 which are connected to a data bus 910.

In one embodiment, the computer system 900 may include a portable device, e.g., a mobile phone, an MPEG audio layer-3 (MP3) player, an MPEG audio layer-4 (MP4) player, a personal digital assistant (PDA), or a portable media player (PMP). In another embodiment, the computer system 900 may include a data processing system, e.g., a personal computer (PC), a notebook-sized personal computer, or a laptop computer. In another embodiment, the computer system 900 may include a memory card, e.g., a secure digital (SD) card or a multi-media card (MMC). In another embodiment, the computer system 900 may include, for example, a smart card or a solid-state drive (SSD).

The memory device 10, the memory controller 950, and the processor 920 may be embodied as one chip, e.g., a SoC. In another embodiment, they may be embodied as separate and independent devices.

In one embodiment, the processor 920 may process input data input via the first interface 930 and write it to the memory device 10. In one embodiment, the processor 920 may read data stored in the memory device 10 and output it to a device via the first interface 930. In this case, the first interface 930 may be an input/output device.

The second interface 940 may be an interface for wireless communication. In one embodiment, the second interface 940 may be embodied by software or firmware. The memory controller 950 corresponds to the memory controller 300 of FIG. 1.

The control units, processors, controllers, and other units and circuits of the present embodiments may be implemented in logic which, for example, may include hardware, software, or both. When implemented at least partially in hardware, the control units, processors, controllers, and other units and circuits may be, for example, any one of a variety of integrated circuits including but not limited to an application-specific integrated circuit, a field-programmable gate array, a combination of logic gates, a system-on-chip, a microprocessor, or another type of processing or control circuit.

When implemented in at least partially in software, the control units, processors, controllers, and other units and circuits may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods herein.

In accordance with one or more of the aforementioned embodiments, specific information may be shared via one or more TSVs in a memory system, thereby simplifying circuitry and reducing chip size. Furthermore, a memory system may be provided with a simplified circuit configuration to decrease power consumption.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the embodiments set forth in the claims.

What is claimed is:

1. A memory system, comprising:
a plurality of memory devices; and
a plurality of first signal lines to connect the memory devices to one another, wherein the memory devices include:
a first memory device including at least one fuse cell, the first memory device to output fuse information set based on whether each of the at least one fuse cell is programmed; and
at least one second memory device to receive the fuse information and to selectively activate the first signal lines based on the fuse information, wherein the at least one second memory device simultaneously operates based on the fuse information received from the first memory device.

2. The memory system as claimed in claim 1, wherein the first memory device includes:
a first sub-fuse cell array to store first fuse information corresponding to memory cells in the first memory device; and
a second sub-fuse cell array to store second fuse information corresponding to the first signal lines, and
the at least one second memory device includes a first sub-fuse cell array to store first fuse information corresponding to memory cells in the at least one second memory device.

3. The memory system as claimed in claim 2, wherein:
the first fuse information includes information indicating whether at least one of the memory cells is defective, and
the second fuse information includes information indicating whether at least one among the first signal lines is defective.

4. The memory system as claimed in claim 3, wherein the first memory device includes:
a clock signal generator to generate a fuse information clock signal to be synchronized with the second fuse information; and
a fuse information transmission circuit to transmit the second fuse information to the at least one second memory device based on the fuse information clock signal.

5. The memory system as claimed in claim 4, wherein the second fuse information includes serial data corresponding to each of the first signal lines.

6. The memory system as claimed in claim 4, wherein:
the first signal lines are to transmit a control signal and data between the first memory device and the at least one second memory device, and
the memory system includes a second signal line to transmit the second fuse information and the fuse information clock signal from the first memory device to the at least one second memory device.

7. The memory system as claimed in claim 6, wherein each of the first signal lines and the second signal line includes a through-silicon via (TSV).

8. The memory system as claimed in claim 1, wherein the memory devices have a three-dimensional (3D) stack structure.

9. A memory system, comprising:
a first memory device including at least one fuse cell, the first memory device to store fuse information set according to whether each of the at least one fuse cell is programmed and to output the stored fuse information;
a second memory device including a fuse information storage area to receive and store the fuse information from the first memory device, the second memory device to operate according to the fuse information; and
a fuse information signal line connected between the first memory device and the second memory device, the fuse information signal line to transmit the fuse information from the first memory device to the second memory device.

10. The memory system as claimed in claim 9, wherein the first memory device includes:
a fuse information transmission circuit to convert the fuse information into serial data and to transmit the serial data to the second memory device in synchronization with a fuse information clock signal; and
a clock signal generator to generate the fuse information clock signal.

11. The memory system as claimed in claim 10, further comprising:
a clock signal line connected between the first memory device and the second memory device, the clock signal line to transmit the fuse information clock signal from the first memory device to the second memory device.

12. The memory system as claimed in claim 11, wherein the second memory device includes:
a fuse information receiving circuit to receive the serial data of the fuse information via the fuse information signal line, receive the fuse information clock signal via the clock signal line, detect the serial data based on the fuse information clock signal, and store the serial data in the fuse information storage area.

13. The memory system as claimed in claim 11, further comprising:
a third memory device to receive the fuse information from the first memory device via the fuse information signal line, the third memory device to operate according to the fuse information, wherein the first memory device, the second memory device, and the third memory device have a three-dimensional (3D) stack structure.

14. The memory system as claimed in claim 11, wherein each of the fuse information signal line and the clock signal line includes a through-silicon via (TSV).

15. The memory system as claimed in claim 11, further comprising:
a plurality of TSVs to transmit a control signal and data between the first memory device and the second memory device, wherein the fuse information includes information indicating whether at least one of the TSVs is defective.

16. An apparatus, comprising:
a first die;
a second die; and
a through-silicon via (TSV) between the first and second dies,
wherein the first die includes a storage area to store fuse information for the second die and wherein the fuse information is indicative of whether a signal line between the first and second dies is defective.

17. The apparatus as claimed in claim 16, wherein:
the storage area includes a fuse cell array, and
wherein the second die is to operate based on the fuse information received from the fuse cell array.

18. The apparatus as claimed in claim 16, wherein:
the first die includes a clock signal generator to generate a fuse information clock signal, and
the first die is to transmit the fuse information based on the fuse information clock signal.

19. The apparatus as claimed in claim 16, wherein the signal line is the TSV or another TSV between the first and second dies.

20. The apparatus as claimed in claim 16, wherein:
the first die is a buffer die, and
the second die is a core die.
